(19) United States
(12) Patent Application Publication
(10) Pub. No.: US 2012/0015468 A1
(43) Pub. Date: Jan. 19, 2012

(54) SURFACE MOUNT MEMS DEVICE STRUCTURE AND FABRICATING METHOD THEREOF FOR CRYSTAL OSCILLATORS

(76) Inventor: CHI-HSUN KUO, Taipei City (TW)

(21) Appl. No.: 12/837,612

(22) Filed: Jul. 16, 2010

(51) Int. Cl. H01L 21/50

(52) U.S. Cl. 438/51; 257/E21.499

(57) ABSTRACT

A method of fabricating surface mount micro electro mechanical systems (MEMS) device includes forming SMD MEMS crystal oscillator devices on wafer and forming its bonding structure, also can either use lithographic packing process or single package mount bonding crystal blanks packing process. The method further includes embedded crystal device into the integrated circuit, it effectively to eliminate the use of extra the discrete components, reduced the fabrication cost and fail rate for system in package (SIP) or chip on board (COB) packing.

### BACKGROUND OF THE INVENTION

1. Field of the Invention

The present invention related to a method of fabricating a surface mount micro electro mechanical systems(MEMS) crystal oscillator device, and particular enable embedded into integrated circuit with microprocessor control unit(MCU) or any other integrated circuit devices, particularly for system in package(SIP) and chip on board(COB) or any other similar packing process.

2. Description of the Prior Art

Almost all electronic instruments and communication system require a time base reference frequency by quartz crystal. Such as TV, radio, personal computer, Printer, Network interface card, Bluetooth peripherals and mobile devices etc. Crystal oscillator has several advantages over other resonators because it precision time standards, especially with regard to temperature stability and low power consumption. However the current existing discrete crystal oscillator is not compatible with IC packing process. Due to the different coefficient of thermal expansion (CTE), will cause the reliability problem.

A crystal oscillator is an electronic circuit that uses the mechanical resonance of a vibrating crystal of piezoelectric material to create an electrical signal with a very precise and stable frequency. When a crystal of quartz is properly cut and mounted, it can be made to distort in an electric field by applying a voltage to an electrode near or on the crystal. This property is known as piezoelectricity. When the field is removed, the quartz will generate an electric field as it returns to its previous shape, and this can generate a voltage. The result is that a quartz crystal behaves like a circuit composed of an inductor, capacitor and resistor, with a precise resonant frequency.

Current surface mount crystal resonator use ceramic base and seam sealed with metal lid, or covered with same ceramic material. It fabrication technology comes alone with high power to seam seal the metal lid or oven to melt the epoxy glue with it cover. Due to the different coefficient of thermal expansion (CTE), traditional seam sealed crystal resonators would break in the hermetic environment of it and cause unstable frequency or terminate the oscillation. As the reason above, the present invention implement the defect.

### SUMMARY OF THE INVENTION

The present invention relates to a method of fabricating a surface mount micro electro mechanical system (MEMS) crystal oscillator device on glass wafer, resulting into low cost, high temperature stability, smaller form factors, increased reliability and manufacturability compatible with integrated circuit and single chip solution.

Additional to the related invention, its special designed structure of adhesive area effectively decreased ungluing or bad adhesive while fabricating.

In the following detailed description of the invention, reference is made to the accompanying drawings the show specific embodiments in which the invention may be practiced. These embodiments are described in sufficient detail to enable those skilled in the art to practice the invention. Other embodiments may be utilized and changes made without departing from the scope of the present invention. The following detailed description is not to be taken in a limiting sense, and the scope of the present invention is defined only be the appended claims.

### BRIEF DESCRIPTION OF THE DRAWINGS

The drawings disclose an illustrative embodiment of the present invention which serves to exemplify the various advantages and objects hereof, and are as follows:

FIG. 1 is the schematic diagram of a fabricating process.

FIG. 2A is top view of the glass wafer.

FIG. 2B is the cross-sectional diagram of glass wafer.

FIG. 2C is the front top view of the glass wafer after plated the circuits.

FIG. 2D is the back top view of the glass wafer after plated.

FIG. 3A is the top view of the cover over the glass wafer.

FIG. 3B is a schematic cross-sectional diagram of the glass cover wafer glued.

FIG. 4A is the top view of crystal blanks on a tray.

FIG. 4B is the top view after crystal blank mounted on the glass wafer by mounting machine.

FIG. 5A is the top view after all the crystal blank mounted on the glass wafer.

FIG. 5B is a schematic cross-sectional diagram of a crystal blank mounted on the glass wafer.

FIG. 6A is a schematic cross-sectional diagram of a SMD MEMS crystal oscillator.

FIG. 6B is the other side of a schematic cross-section diagram of a SMD MEMS crystal oscillator.

FIG. 7A is a schematic diagram of glass wafer forming a hermetic environment for SMD MEMS crystal resonators.

FIG. 7B is a schematic diagram for disc saw dicing SMD MEMS crystal resonators.

### DETAILED DESCRIPTION OF THE PREFERRED EMBODIMENT

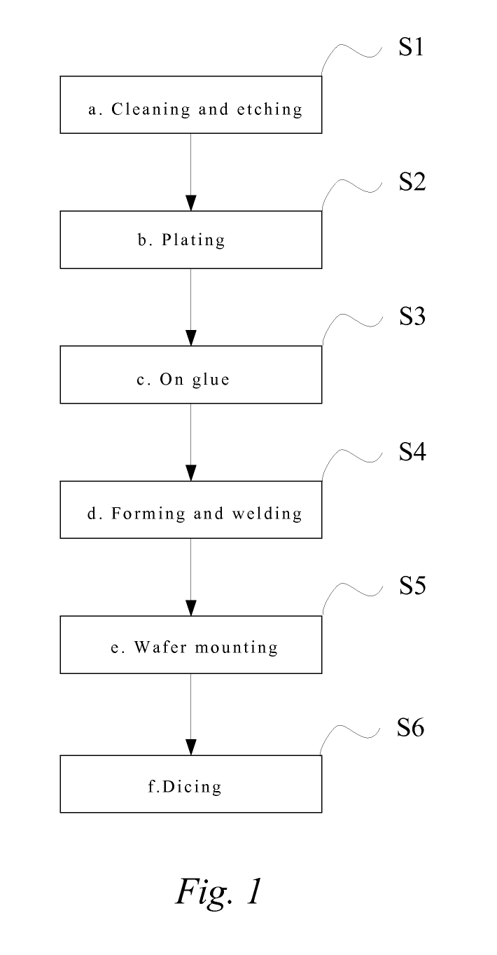

As shown in FIG. 1, the method of present invention begins by cleaning and etching S1. The S1 may be any type of packaging element. In example embodiment, the substrate is a glass wafer.

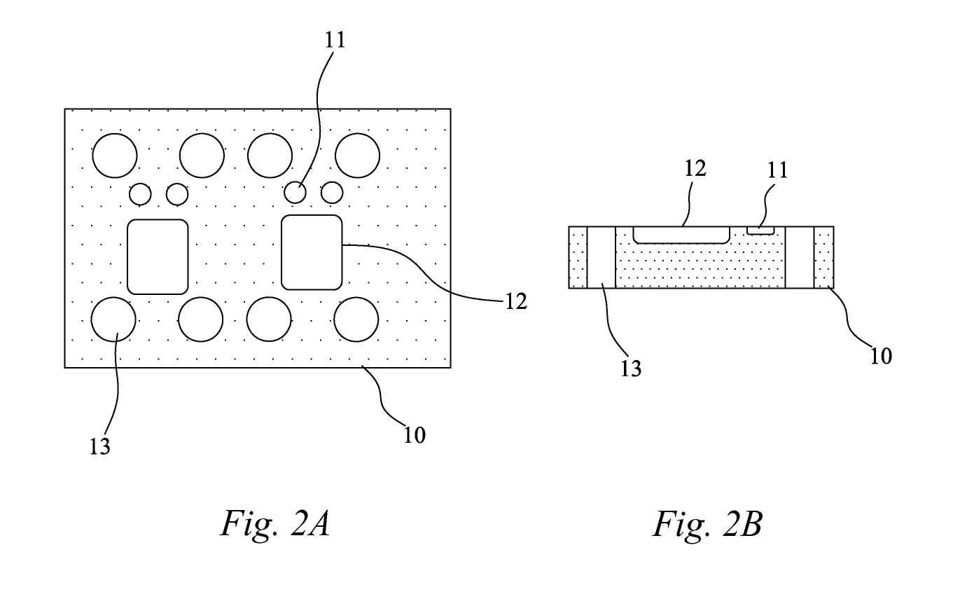

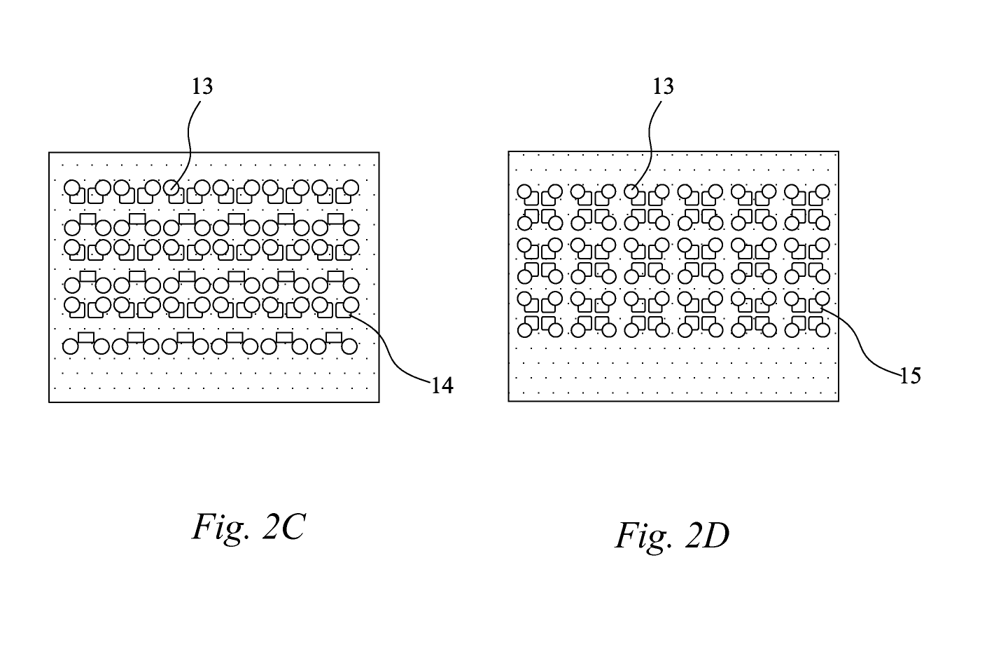

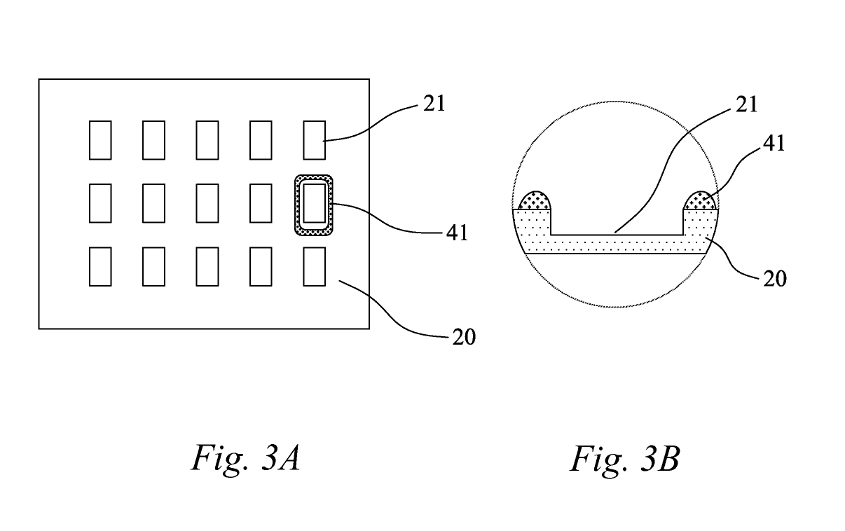

FIG. 2A shows the top view and FIG. 2B is the schematic cross-section of glass wafer. 10 can be 3 to 12 inches glass wafer and etch through holes 13 with diameter around 50 to 150 um and numbers of cavities 12 which depth around 3 to 5 um with dimension under 1.7 mm×2.0 mm. The cover cap 20 etching shown as FIG. 3A and it cross-section diagram as FIG. 3B shows the glue positioned within the ring 41 complied with FIG. 2 cavity 12.

As shown in FIG. 2 C is the front top view on wafer after plating circuits 14. And B is the back top view on wafer after plating circuit 15, both connected through hole shown in FIG. 2 B 13.

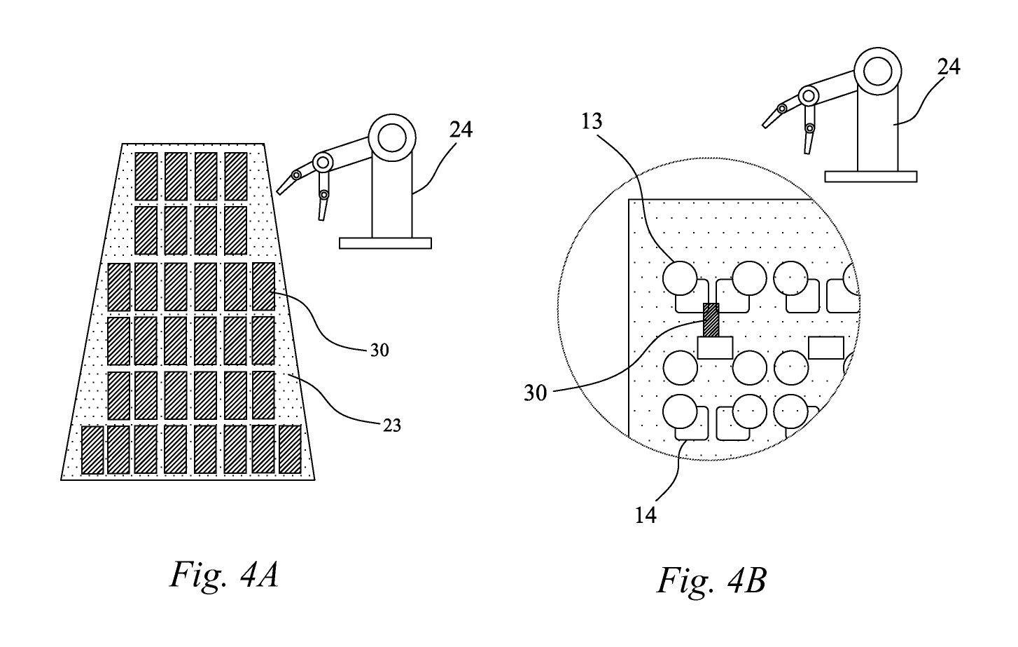

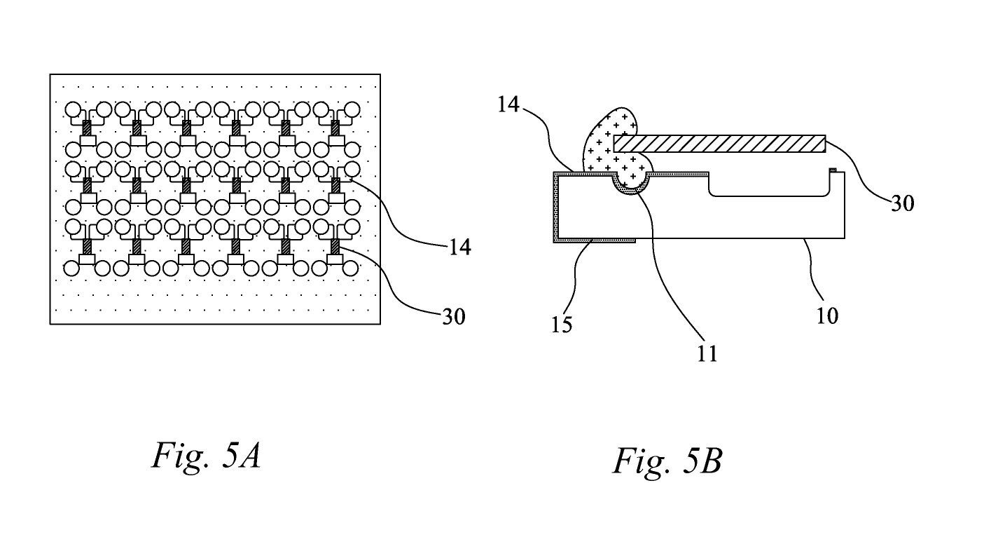

As shown in FIGS. 4A and 4B, the crystal blanks 30 placed on a mask substrate 23. Crystal blanks 30 can be mounted on the FIG. 2A. either by lithographic screen printing on glue or machine arms 24 shown in FIG. 4A. After crystal blank put on the wafer shown in FIG. 5A. would again glue on the crystal blank to connect the electricity and enhance the structure shown as FIG. 5B.

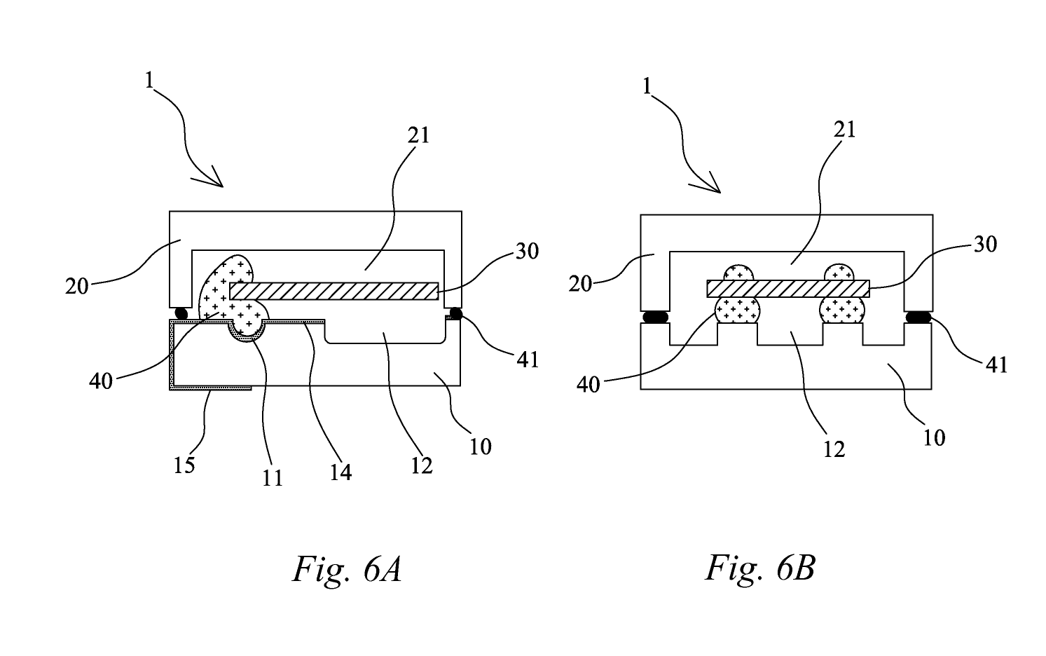

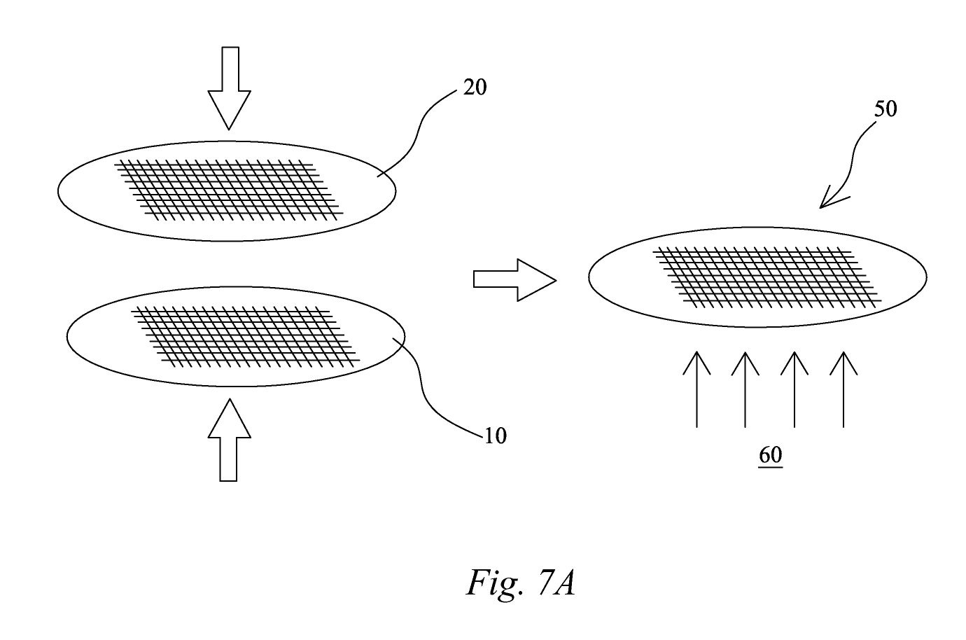

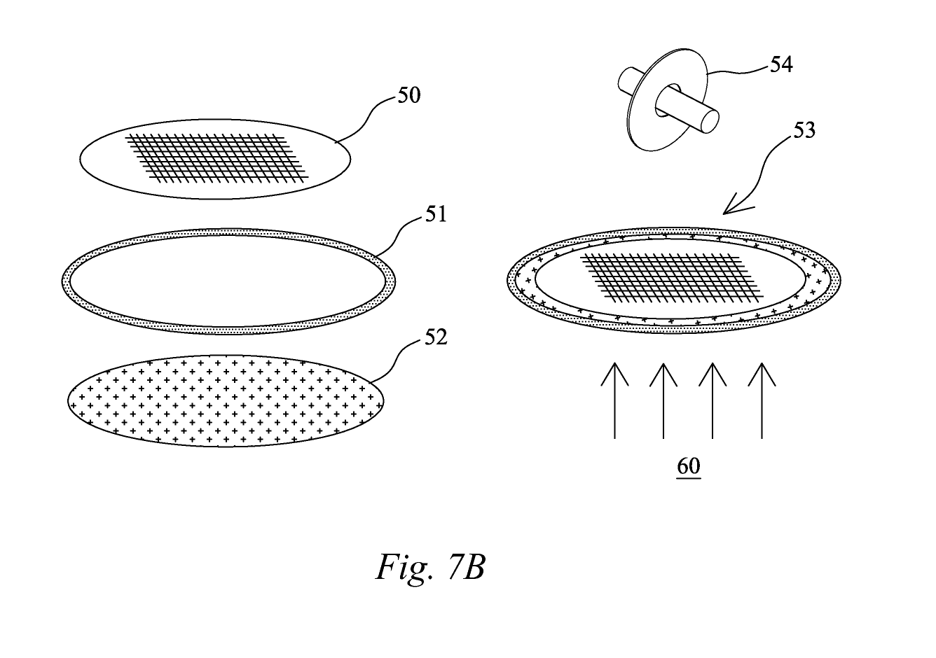

As shown in FIG. 6A, it is a schematic cross-section diagram of hermetic environment of crystal oscillator. With the base cavity 10 and UV glue 41 covered with wafer 20 under 200 watts UV light 1 hour exposure. And form a wafer as FIGS. 7A and 7B.

As shown in FIG. 7B, put the wafer 50 on blue tape 52 with expend ring 51. After UV light 60 exposed into formed wafer 53. And dicing with thickness of 100 um to 120 um disc saw for further fabrication comply with integrated circuit.

Although specific embodiments have been illustrated and described herein, it will be appreciated by those of ordinary skill in the art that any arrangement which achieves the same purpose may be substituted for the embodiments shown. This application is intended to cover any adaptations or variations of the present invention. Therefore, it is manifestly intended that this invention be limited only by the claims and the equivalents thereof

What is claimed is:

1. A method comprising: forming a surface mount micro electro mechanical systems crystal oscillator device embedded with integrated circuit devices.

2. The method of claim 1, wherein forming a hermetic environment includes etching on the wafer or any type of form of package material and plating a conductive layer of it circuit.

3. The method of claim 1, wherein forming a special adhesive area bonding the crystal blank to the wafer, the bonding method would either by lithographic printing process or glue machine arms. Wherein bonding cover wafer and bottom wafer with UV lights or other adhesive material to fix on the blue tape and dicing the unit with embedded crystal blank.

4. The method of claim 3, wherein the cover and bottom wafer size at least 3 inches.

5. The method of claim 3, wherein the crystal blank may be quartz or any other piezoelectric materials.

6. The method of claim 3, wherein the cavities on wafer should at least two in each and in round shaped.
